(19) United States
(12) Patent Application Publication
(10) Pub. No.: US 2026/0121395 A1
(43) Pub. Date: Apr. 30, 2026

(54) SERVER OVERCURRENT PROTECTION CIRCUIT AND METHOD, SERVER, AND NON-VOLATILE COMPUTER READABLE STORAGE MEDIUM

(71) Applicant: SUZHOU METABRAIN INTELLIGENT TECHNOLOGY CO., LTD., Suzhou, Jiangsu (CN)

(72) Inventor: Zhuang LIANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 19/469,836

(22) PCT Filed: Dec. 13, 2024
(86) PCT No.: PCT/CN2024/139406

§ 371 Date: Sep. 26, 2025

(30) Foreign Application Priority Data
Jan. 31, 2024 (CN) 202410133273.7

(51) Int. Cl. H02H 3/05; H02H 3/00; H02H 3/087; H03K 17/12

(52) U.S. Cl. CPC H02H 3/05; H02H 3/006; H02H 3/087; H03K 17/12

(57) ABSTRACT

Provided are a server Over Current Protection (OCP) circuit and method, a server, and a non-volatile computer readable storage medium. The server OCP circuit can include: a BMC, a CPLD, an Electronic Fuse (EFUSE), a light-emitting diode, and a photoresistor, wherein the BMC is connected to the CPLD, the CPLD is connected to the EFUSE, the CPLD is grounded through the light-emitting diode, the EFUSE can connect to an access device, and the EFUSE is grounded through the photoresistor; the CPLD can output a control signal corresponding to OCP control information corresponding to configuration information of the access device to the light-emitting diode, so as to control the brightness of the light-emitting diode to further control a resistance value of the photoresistor; and the EFUSE can set a current threshold for OCP based on the resistance value of the photoresistor.

### CROSS-REFERENCE TO RELATED APPLICATION

This application is a National Stage Entry under 35 U.S.C. § 371 of PCT International Application No. PCT/CN2024/139406, filed on Dec. 13, 2024, which claims priority to Chinese Patent Application No. 202410133273.7, filed to the China National Intellectual Property Administration on Jan. 31, 2024 and entitled “Server Over Current Protection Circuit and Method, Server, and Storage Medium”, the entire contents of each of which are incorporated herein by reference for all purposes.

### TECHNICAL FIELD

The present disclosure relates to the technical field of computers, and in particular, to a server Over Current Protection (OCP) circuit and method, a server, and a non-volatile computer readable storage medium.

### BACKGROUND

At present, servers usually implement OCP of circuits using specialized Electronic Fuse (EFUSE) Integrated Circuits (ICs). With the continuous improvement in requirements of customers for server configurations, the server configurations are becoming more and more diversified. At the same time, in order to meet the compatibility of a board, the same motherboard needs to interface with different service modules on different devices. However, different service modules are often designed by different vendors, resulting in various differences in internal circuits and functionality. Therefore, the current requirements of each service module are different during normal operation. It is often unreasonable to set the same OCP parameters on the motherboard for different service modules, as this may cause irrecoverable damage to a server. For example, if an OCP point is set too high, an EFUSE of the server may fail to shut down in time when a short circuit or component failure occurs. Consequently, the EFUSE fails to provide OCP, resulting in the problems such as the burnout of the service module. Therefore, in the related art, the effectiveness and reliability of OCP for a power supply are low.

Therefore, there is a technical problem in the related art that the effectiveness and reliability of OCP are low.

### SUMMARY

An objective of the present disclosure is to provide a server OCP circuit and method, a server, and a non-volatile computer readable storage medium, so as to improve the effectiveness and reliability of OCP.

In order to achieve the above objective, the present disclosure provides a server OCP circuit, which comprising: a controller (namely, Baseboard Management Controller, BMC), a logic device (namely, Complex Programmable Logic Device, CPLD), an Electronic Fuse (EFUSE), a light-emitting diode, and a photoresistor, wherein the controller is connected to the logic device, the logic device is connected to the EFUSE, the logic device is grounded through the light-emitting diode, the EFUSE is configured to connect to an access device, and the EFUSE is grounded through the photoresistor;
the controller is configured to transmit OCP control information corresponding to configuration information of the access device to the logic device;
the logic device is configured to output a control signal corresponding to the OCP control information to the light-emitting diode to control brightness of the light-emitting diode through the control signal, and to control a resistance value of the photoresistor by controlling the brightness of the light-emitting diode; and
the EFUSE is configured to set a current threshold for OCP based on the resistance value of the photoresistor.

The server OCP circuit further comprises a Platform Controller Hub (PCH). The PCH is connected to the controller.

The PCH is configured to, in a case where a server is powered on or it is detected that the access device connects to the server, acquire the configuration information of the access device, and transmit the configuration information to the controller.

The PCH is connected to the controller through an Enhanced Serial Peripheral Interface (eSPI) bus or a Low Pin Count (LPC) bus.

The controller is configured to convert the configuration information of the access device into the OCP control information and transmit the OCP control information to the logic device.

The the controller is configured to query the OCP control information corresponding to the configuration information of the access device from a flash and transmit the OCP control information to the logic device.

The logic device is further configured to store the OCP control information in a storage area inside the logic device.

The storage area is a User Flash Memory (UFM).

The controller is further configured to transmit the control signal corresponding to the OCP control information to the logic device.

The logic device is configured to determine whether the controller is in a normal operating state; in a case where it is determined that the controller is in the normal operating state, switch to a link through which the control signal is received from the controller and is output to the light-emitting diode, so that the controller controls the brightness of the light-emitting diode through the control signal, and controls the resistance value of the photoresistor by controlling the brightness of the light-emitting diode; and in a case where it is determined that the controller is not in the normal operating state, switch to a link through which the control signal is output from the logic device to the light-emitting diode, read the OCP control information from the storage area, and output the control signal corresponding to the OCP control information to the light-emitting diode, so as to control the brightness of the light-emitting diode through the control signal, and control the resistance value of the photoresistor by controlling the brightness of the light-emitting diode.

The logic device is configured to determine whether the controller is in the normal operating state by detecting a Watchdog Timer (WDT) signal sent from the controller to the logic device.

The logic device comprises a Multiplexer (MUX), and the logic device is configured to control the MUX, via an enable signal, to switch to the link through which the control signal is received from the controller and is output to the light-emitting diode or the link through which the control signal is output from the logic device to the light-emitting diode.

The control signal is a Pulse Width Modulation (PWM) control signal.

In order to achieve the above objective, the present disclosure provides a server, which comprises the above server OCP circuit.

In order to achieve the above objective, the present disclosure provides a server OCP method (namely, a method for protecting a server from over current), which is applied to a logic device in the above server OCP circuit. The method comprises the following operations:
acquiring OCP control information corresponding to configuration information of an access device; and
outputting a control signal corresponding to the OCP control information to a light-emitting diode to control brightness of the light-emitting diode through the control signal, and control a resistance value of a photoresistor by controlling the brightness of the light-emitting diode, so that an Electronic Fuse (EFUSE) sets a current threshold for OCP based on the resistance value of the photoresistor.

The acquiring OCP control information corresponding to configuration information of an access device comprises:
acquiring the OCP control information corresponding to the configuration information of the access device from a controller.

After acquiring the OCP control information corresponding to the configuration information of the access device, the method further comprises:
storing the OCP control information in a storage area inside the logic device.

Before outputting the control signal corresponding to the OCP control information to the light-emitting diode, the method further comprises:
receiving the control signal corresponding to the OCP control information transmit by the controller.

The outputting a control signal corresponding to the OCP control information to a light-emitting diode to control brightness of the light-emitting diode through the control signal, and control a resistance value of a photoresistor by controlling the brightness of the light-emitting diode comprises:
determining whether the controller is in a normal operating state;
in a case where it is determined that the controller is in the normal operating state, switching to a link through which the control signal is received from the controller and is output to the light-emitting diode, so that the controller controls the brightness of the light-emitting diode through the control signal, and controls the resistance value of the photoresistor by controlling the brightness of the light-emitting diode; and
in a case where it is determined that the controller is not in the normal operating state, switching to a link through which the control signal is output from the logic device to the light-emitting diode, reading the OCP control information from the storage area, and outputting the control signal corresponding to the OCP control information to the light-emitting diode to control the brightness of the light-emitting diode through the control signal, and control the resistance value of the photoresistor by controlling the brightness of the light-emitting diode.

The switching to a link through which the control signal is received from the controller and is output to the light-emitting diode comprises:
controlling, via an enable signal, a Multiplexer (MUX) inside the logic device to switch to the link through which the control signal is received from the controller and is output to the light-emitting diode.

Accordingly, the switching to a link through which the control signal is output from the logic device to the light-emitting diode comprises:
controlling, via the enable signal, the MUX inside the logic device to switch to the link through which the control signal is output from the logic device to the light-emitting diode.

In order to achieve the above objective, the present disclosure provides a non-volatile computer readable storage medium, in which a computer program is stored. The computer program is executed by a processor to implement the steps of the above server OCP method.

As can be seen from the above solutions, the server OCP circuit provided by the present disclosure comprises the controller, the logic device, the EFUSE, the light-emitting diode, and the photoresistor. The controller is connected to the logic device, the logic device is connected to the EFUSE, the logic device is grounded through the light-emitting diode, the EFUSE is connected to the access device, and the EFUSE is grounded through the photoresistor. The controller is configured to transmit the OCP control information corresponding to the configuration information of the access device to the logic device. The logic device is configured to output the control signal corresponding to the OCP control information to the light-emitting diode to control the brightness of the light-emitting diode through the control signal, and to control the resistance value of the photoresistor by controlling the brightness of the light-emitting diode. The EFUSE is configured to set the current threshold for OCP based on the resistance value of the photoresistor.

In the present disclosure, the EFUSE is grounded through the photoresistor, the light-emitting diode is arranged near the photoresistor, and the resistance value of the photoresistor may be controlled through the brightness of the light-emitting diode, so that the EFUSE may be controlled to set the corresponding current threshold for OCP by controlling the brightness of the light-emitting diode. When the access device is detected, the current threshold for OCP to be set is determined according to the configuration information of the access device, and the corresponding control signal is sent to the light-emitting diode, so as to control the light-emitting diode to be at an appropriate brightness to further control the resistance value of the photoresistor, thereby controlling the current threshold for OCP of the EFUSE. It can be seen that the server OCP circuit provided by the present disclosure may set the appropriate current threshold for OCP according to different service modules in different access devices, can meet the requirement of the same motherboard being compatible with different service modules, and greatly improve the effectiveness and reliability of OCP, as well as the universality of a board. The present disclosure further discloses the server OCP method, the server, and the non-volatile computer readable storage medium, which can also achieve the above technical effects.

It is to be understood that the above general description and the following detailed description are only exemplary and not intended to limit the present disclosure.

### BRIEF DESCRIPTION OF THE DRAWINGS

In order to more clearly illustrate the embodiments of the present disclosure or the technical solutions in the related art, the drawings used in the description of the embodiments or the related art will be briefly described below. It is apparent that the drawings described below are only some embodiments of the present disclosure. Other drawings may further be obtained by those of ordinary skill in the art according to these drawings without inventive efforts. The drawings are used to provide a further understanding of the present disclosure, constitute a part of the specification, and used to explain the present disclosure together with the following specific implementation, but not to limit the present disclosure. In the drawings:

FIG. 1 is a structural diagram of a server OCP circuit in the related art.

FIG. 2 is a structural diagram of a server OCP circuit according to an exemplary embodiment.

FIG. 3 is a schematic diagram of an internal switching link of a logic device according to an exemplary embodiment.

FIG. 4 is a flowchart of setting a current threshold for OCP according to an exemplary embodiment.

FIG. 5 is a flowchart of a server OCP method according to an exemplary embodiment.

FIG. 6 is a flowchart of another server OCP method according to an exemplary embodiment.

### DETAILED DESCRIPTION OF THE EMBODIMENTS

The technical solutions in the embodiments of the present disclosure will be clearly and completely described in conjunction with the drawings in the embodiments of the present disclosure. It is apparent that the described embodiments are only a part of the embodiments of the present disclosure, and not all of them. All other embodiments obtained by those ordinary skill in the art on the basis of the embodiments of the present disclosure without inventive efforts are within the scope of the present disclosure. In addition, “first”, “second” and the like in the embodiments of the present disclosure are used to distinguish similar objects, and are not necessarily used to describe a specific order or sequence.

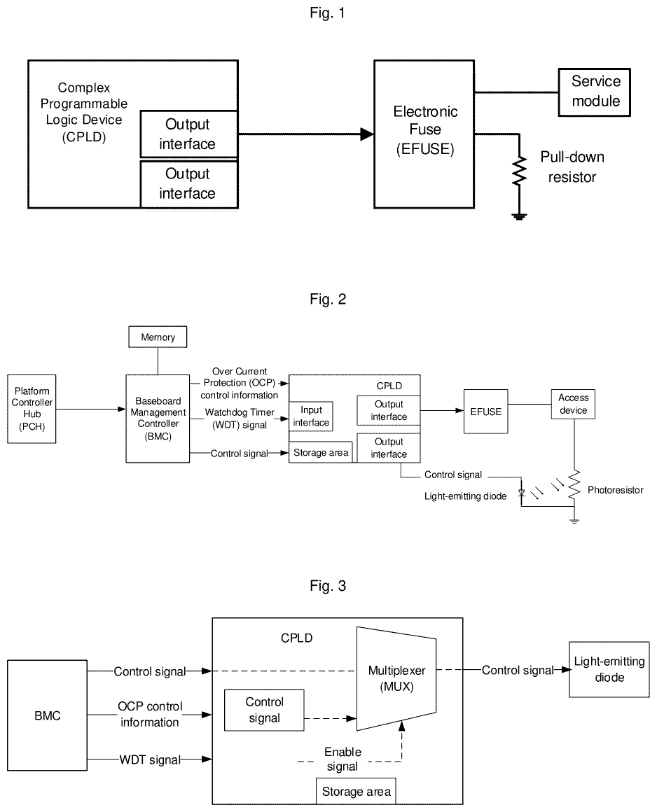

At present, servers usually implement OCP of circuits using specialized EFUSE ICs. As shown in FIG. 1, using an integrated EFUSE, a current threshold for OCP is set by adding a pull-down resistor. When a current passing through the EFUSE exceeds this threshold, the EFUSE is triggered to provide OCP.

By consulting the specification of a service module, a designer confirms a peak to peak current (pp current), sets the current threshold for OCP to 1.2-1.5 times the maximum current, then determines a calculation method for the pull-down resistor (Rset) based on the specification of the EFUSE, and selects an appropriate resistor Rset, thereby setting the current threshold for OCP.

With the continuous improvement in requirements of customers for server configurations, the server configurations are becoming more and more diversified, so that the same power supply is connected to different service modules to provide power. Therefore, an OCP threshold for OCP can only be set based on the largest service module. Setting the current threshold solely based on the largest service module inevitably results in insufficient OCP for the service module with low current. Excessive current may cause the damage to the service module, posing a significant risk. It can be seen that, in the related art, the automatic adjustment of the current threshold according to different service modules cannot be achieved.

In addition, when other projects need to reuse a board or the server configurations are diversified, it is necessary to change the pull-down resistor Rset according to the actual configuration to set the OCP threshold. Therefore, board sharing cannot be achieved, thereby increasing the manpower and maintenance costs of the board.

Therefore, in the present disclosure, the EFUSE is grounded through a photoresistor, and a resistance value of the photoresistor may be controlled through the brightness of a light-emitting diode, so that the EFUSE may be controlled to set the corresponding current threshold for OCP by controlling the brightness of the light-emitting diode. When an access device is detected, the current threshold for OCP to be set is determined based on the configuration information of the access device, and a corresponding control signal is sent to the light-emitting diode, so as to control the light-emitting diode to be at an appropriate brightness to further control the resistance value of the photoresistor, thereby controlling the current threshold for OCP of the EFUSE. It can be seen that the server OCP circuit provided by the present disclosure may set the appropriate current threshold for OCP based on different service modules in different access devices, can meet the requirement of the same motherboard being compatible with different service modules, and greatly improve the effectiveness and reliability of OCP, as well as the universality of the board.

The present embodiment provides a server OCP circuit, as shown in FIG. 2, which comprises: a controller (which may be, but is not limited to, a Baseboard Management Controller (BMC), a logic device (which may be, but is not limited to, a Complex Programmable Logic Device (CPLD), an EFUSE, a light-emitting diode, and a photoresistor. The controller is connected to the logic device, the logic device is connected to the EFUSE, the logic device is grounded through the light-emitting diode, the EFUSE is configured to connect to an access device, and the EFUSE is grounded through the photoresistor.

The controller is configured to transmit OCP control information corresponding to configuration information of the access device to the logic device.

The logic device is configured to output a control signal corresponding to the OCP control information to the light-emitting diode to control brightness of the light-emitting diode through the control signal, and to control a resistance value of the photoresistor by controlling the brightness of the light-emitting diode.

The EFUSE is configured to set a current threshold for OCP based on the resistance value of the photoresistor.

As one feasible implementation, the server OCP circuit further comprises a PCH. The PCH is connected to the controller. The PCH is configured to, in a case where a server is powered on or it is detected that the access device connects to the server, acquire the configuration information of the access device, and transmit the configuration information to the controller.

In an optional implementation, when the server is powered on or the access device is detected to access the server, the PCH acquires the configuration information of the access device, and transmits the configuration information to the controller. The access device here may be a Peripheral Component Interconnect Express (PCIe) device, and the configuration information may be a peak to peak current of a service module in the access device. As one feasible implementation, the PCH is connected to the controller through an eSPI bus or an LPC bus.

Further, the controller determines the OCP control information corresponding to the configuration information. As one feasible implementation, the controller is configured to convert the configuration information of the access device into the OCP control information and transmit the OCP control information to the logic device. In an optional implementation, the controller calculates the corresponding OCP information according to the received configuration information.

As another possible implementation, the controller is configured to query the OCP control information corresponding to the configuration information of the access device from a flash and transmit the OCP control information to the logic device. In an optional implementation, a correspondence between the configuration information and the OCP control information may be pre-stored in the flash, and the controller queries the OCP control information corresponding to the received configuration information in the flash.

The OCP control information in the present embodiment may be the current threshold for OCP, the resistance value of the photoresistor, the control signal for controlling the light-emitting diode, etc., which is not is not limited herein. When the current threshold for OCP is calculated based on the configuration information, a preset multiple, such as 1.2-1.5 times, of the peak to peak current of the service module in the access device may be calculated as the current threshold for OCP, the resistance value of the photoresistor may be calculated based on the current threshold for OCP and the specification of the EFUSE, and then the control signal for controlling the light-emitting diode may be determined based on the control of the photoresistor by the light-emitting diode.

Further, the controller transmits the OCP control information to the logic device. The logic device stores the OCP control information in a storage area inside the logic device. As one feasible implementation, the storage area is a User Flash Memory (UFM).

In an optional implementation, the logic device outputs the control signal corresponding to the OCP control information to the light-emitting diode, so as to control the light-emitting diode to be at an appropriate brightness to further control the resistance value of the photoresistor, thereby controlling the current threshold for OCP of the EFUSE. As one feasible implementation, the control signal is a PWM control signal.

As one feasible implementation, the controller is further configured to transmit the control signal corresponding to the OCP control information to the logic device. In an optional implementation, the controller transmits the OCP control information to the logic device, and simultaneously transmits the control signal corresponding to the OCP control information to the logic device. The control signal is configured to control the brightness of the light-emitting diode when the controller is in a normal operating state.

As one feasible implementation, the logic device is configured to:
determine whether the controller is in a normal operating state; in a case where it is determined that the controller is in the normal operating state, switch to a link through which the control signal is received from the controller and is output to the light-emitting diode, so that the controller controls the brightness of the light-emitting diode through the control signal, and controls the resistance value of the photoresistor by controlling the brightness of the light-emitting diode; and in a case where it is determined that the controller is not in the normal operating state, switch to a link through which the control signal is output from the logic device to the light-emitting diode, read the OCP control information from the storage area, and output the control signal corresponding to the OCP control information to the light-emitting diode, so as to control the brightness of the light-emitting diode through the control signal, and control the resistance value of the photoresistor by controlling the brightness of the light-emitting diode.

In an optional implementation, the logic device is configured to determine whether the controller is in the normal operating state by detecting a Watchdog Timer (WDT) signal sent from the controller to the logic device. When it is detected that the WDT signal is normal, it is determined that the controller is in the normal operating state, otherwise it is determined that the controller is in an abnormal operating state.

As one feasible implementation, the logic device comprises a Multiplexer (MUX), and the logic device is configured to control the MUX, via an enable signal, to switch to the link through which the control signal is received from the controller and is output to the light-emitting diode or the link through which the control signal is output from the logic device to the light-emitting diode.

In an optional implementation, a schematic diagram of an internal switching link of the CPLD is shown in FIG. 3. In a case where the controller (which may be, but is not limited to, the BMC) is in the normal operating state, the internal MUX of the logic device (which may be, but is not limited to, the CPLD) is controlled, via the enable signal, to switch to the link through which the control signal is received from the controller and is output to the light-emitting diode, so as to achieve transparent transmission of the control signal from the controller, thereby achieving the brightness control of the light-emitting diode by the controller. In a case where the controller is in the abnormal operating state, the internal MUX of the logic device is controlled, via the enable signal, to switch to the link through which the control signal is output from the logic device to the light-emitting diode. The OCP control information is read from the internal storage area, the corresponding control signal is output to control the brightness of the light-emitting diode until the logic device detects that the controller is in the normal operating state again, the control right is returned to the controller again, and the controller continues to control the brightness of the light-emitting diode.

In the embodiment of the present disclosure, the EFUSE is grounded through the photoresistor, the light-emitting diode is arranged near the photoresistor, and the resistance value of the photoresistor may be controlled through the brightness of the light-emitting diode, so that the EFUSE may be controlled to set the corresponding current threshold for OCP by controlling the brightness of the light-emitting diode. When the access device is detected, the current threshold for OCP to be set is determined based on the configuration information of the access device, and the corresponding control signal is transmitted to the light-emitting diode, so as to control the light-emitting diode to be at an appropriate brightness to further control the resistance value of the photoresistor, thereby controlling the current threshold for OCP of the EFUSE. It can be seen that the server OCP circuit provided by the embodiment of the present disclosure may set the appropriate current threshold for OCP based on different service modules in different access devices, can meet the requirement of the same motherboard being compatible with different service modules, and greatly improve the effectiveness and reliability of OCP, as well as the universality of the board.

The embodiments of the present disclosure disclose a server, which comprises a server OCP circuit provided by the above embodiment.

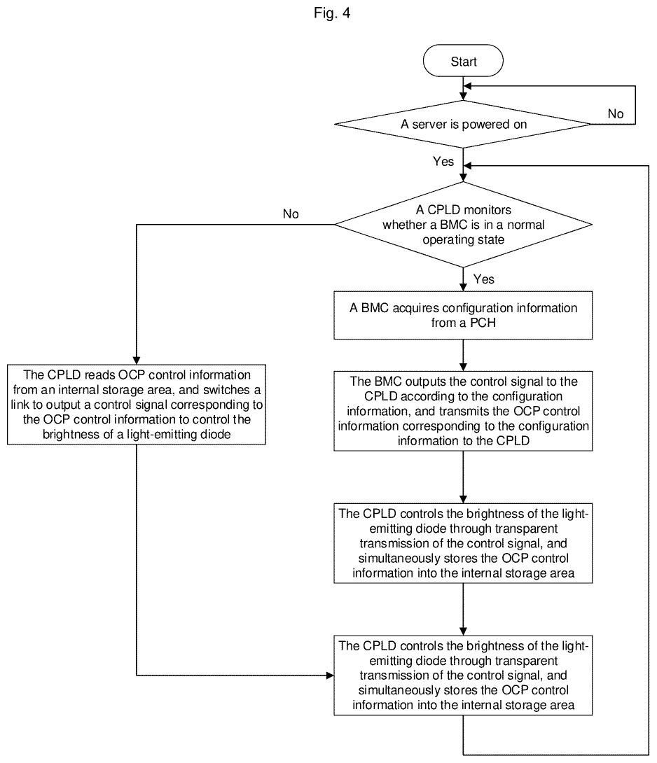

In an optional implementation, a flowchart of setting the current threshold for OCP is shown in FIG. 4. Each time the server is powered on or when the access device is hot-swapped, the PCH acquires the configuration information of the access device, and the PCH transmits the configuration information to the BMC through the eSPI bus or the LPC bus.

The BMC receives the configuration information transmitted from the PCH, analyzes the configuration information, and determines the OCP control information corresponding to the configuration information. As one feasible implementation, the correspondence between the configuration information and the OCP control information may be pre-stored in the flash, and the BMC may query the OCP control information corresponding to the received configuration information in the flash. As another feasible implementation, the BMC calculates the corresponding OCP control information based on the received configuration information. The OCP control information here may be the current threshold for OCP, the resistance value of the photoresistor, the control signal for controlling the light-emitting diode, etc., which is not is not limited herein. When the current threshold for OCP is calculated based on the configuration information, the preset multiple, such as 1.2-1.5 times, of the peak to peak current of the service module in the access device may be calculated as the current threshold for OCP, the resistance value of the photoresistor may be calculated based on the current threshold for OCP and the specification of the EFUSE, and then the control signal for controlling the light-emitting diode may be determined based on the control of the photoresistor by the light-emitting diode.

Further, the BMC transmits the OCP control information to the CPLD through an Inter-Integrated Circuit (I2C), and simultaneously transmits the control signal corresponding to the OCP control information to the CPLD. The control signal is configured to control the brightness of the light-emitting diode when the controller is in the normal operating state. The control signal here may be a PWM waveform, which is not is not limited herein.

The CPLD receives the OCP control information of the BMC and stores same in a storage area inside the logic device. The storage area here may be a UFM storage area, which is not limited herein. The CPLD may detect a state of the WDT signal in real time to monitor whether the BMC operates normally. In a case where the BMC is in the normal operating state, the CPLD detects that the WDT signal is normal. At this time, the internal MUX is controlled, via the enable signal, to switch to the link through which the control signal is received from the BMC, so as to achieve transparent transmission of the control signal from the BMC, thereby achieving the brightness control of the light-emitting diode by the BMC. In a case where the CPLD detects that the WDT signal is abnormal, it indicates that the BMC is in an initialization or hung state at this time, the CPLD takes over the control right of the light-emitting diode, controls the internal MUX of the CPLD, via the enable signal, to switch to an internal link, reads the OCP control information from the storage area, outputs the corresponding control signal to control the brightness of the light-emitting diode until the CPLD detects that the WDT signal is normal again, and returns the control right to the BMC again, and the BMC continues to control the brightness of the light-emitting diode. The logic of the CPLD implements the MUX and other functions, which effectively reduces the cost compared with the use of an independent device.

It can be seen that each time the server is powered on or the service module is hot-swapped, the BMC may update the OCP control information and transmit same to the CPLD, and the CPLD stores the OCP control information in the storage area, so as to avoid inconsistency between the OCP control information stored in the storage area of the CPLD and the OCP control information corresponding to the configuration information of the current access device, resulting in abnormal power failure of the service module or failure to provide effective OCP.

When the brightness of the light-emitting diode changes, the resistance value of the photoresistor changes accordingly. The EFUSE sets the corresponding current threshold for OCP based on the change of the resistance value of the photoresistor, so that different current thresholds for OCP are set for different service modules in different access devices.

In the embodiment of the present disclosure, the EFUSE is grounded through the photoresistor, the light-emitting diode is arranged near the photoresistor, and the resistance value of the photoresistor may be controlled through the brightness of the light-emitting diode, so that the EFUSE may be controlled to set the corresponding current threshold for OCP by controlling the brightness of the light-emitting diode. When the access device is detected, the current threshold for OCP to be set is determined based on the configuration information of the access device, and the corresponding control signal is transmitted to the light-emitting diode, so as to control the light-emitting diode to be at an appropriate brightness to further control the resistance value of the photoresistor, thereby controlling the current threshold for OCP of the EFUSE. It can be seen that the embodiment of the present disclosure may set the appropriate current threshold for OCP based on different service modules in different access devices, can meet the requirement of the same motherboard being compatible with different service modules, and greatly improve the effectiveness and reliability of OCP, as well as the universality of the board.

An application embodiment provided by the present disclosure is described below. The server needs to connect different types of fans, and a correspondence between a model of the fan and the OCP control information is pre-stored in the flash. After the server is powered on or when the fan is connected, the PCH acquires the model of the connected fan and transmits same to the BMC. The BMC queries the OCP control information corresponding to the model in the flash. The BMC transmits the OCP control information to the CPLD, and simultaneously transmits the control signal corresponding to the OCP control information to the CPLD.

The CPLD receives the OCP control information of the BMC and stores same in a storage area inside the logic device. The CPLD detects whether the BMC operates normally in real time. In a case where the BMC is in the normal operating state, the CPLD controls the internal MUX, via an enable signal, to switch to the link through which the control signal is received from the BMC, so as to achieve transparent transmission of the control signal from the BMC, thereby achieving the brightness control of the light-emitting diode by the BMC. In a case where the CPLD detects that the BMC is in the initialization or hung state, the CPLD takes over the control right of the light-emitting diode, controls the internal MUX of the CPLD, via the enable signal, to switch to an internal link, reads the OCP control information from the storage area, outputs the corresponding control signal to control the brightness of the light-emitting diode until the CPLD detects that the BMC is in the normal operating state again, and returns the control right to the BMC again, and the BMC continues to control the brightness of the light-emitting diode.

It can be seen that after the server is powered on or when the fan is connected, the BMC may update the OCP control information of the fan and transmit same to the CPLD, and the CPLD stores the OCP control information in the storage area, so as to avoid inconsistency between the OCP control information stored in the storage area of the CPLD and the OCP control information corresponding to the model of the current connected fan, resulting in failure to provide effective OCP.

When the brightness of the light-emitting diode changes, the resistance value of the photoresistor changes accordingly. The EFUSE sets the corresponding current threshold for OCP based on the change of the resistance value of the photoresistor, so that different current thresholds for OCP are set for different models of fans connected.

The embodiments of the present disclosure disclose a server OCP method, so as to improve the effectiveness and reliability of OCP.

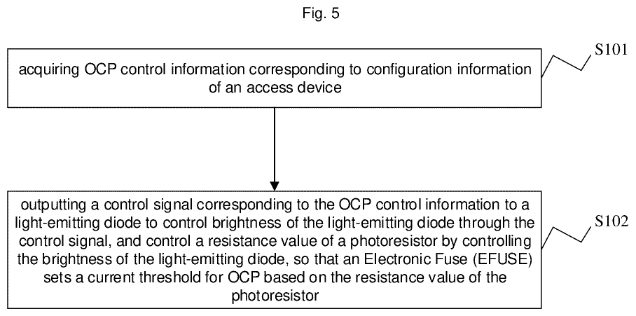

Referring to FIG. 5, a flowchart of a server OCP method based on an exemplary embodiment is shown. As shown in FIG. 5, the method comprises the following operations.

At S101, acquiring OCP control information corresponding to configuration information of an access device.

The execution subject of the present embodiment is a logic device (which may be, but is not limited to, a CPLD in the above server system.

In an optional implementation, when a server is powered on or the access device is detected to access the server, a PCH acquires the configuration information of the access device, and transmits the configuration information to a controller (which may be, but is not limited to, a BMC. As one feasible implementation, the PCH transmits the configuration information to the controller through an eSPI bus or an LPC bus.

Further, the controller determines the OCP control information corresponding to the configuration information. As one feasible implementation, the controller acquires the configuration information of the access device through the PCH, queries the OCP control information corresponding to the configuration information in a flash, and transmits same to the logic device. In an optional implementation, a correspondence between the configuration information and the OCP control information may be pre-stored in the flash, and the controller queries the OCP control information corresponding to the received configuration information in the flash.

As another feasible implementation, the controller acquires the configuration information of the access device through the PCH, converts the configuration information into the corresponding OCP control information, and transmits same to the logic device. In an optional implementation, the controller calculates the corresponding OCP information based on the received configuration information.

The OCP control information in the present embodiment may be a current threshold for OCP, a resistance value of a photoresistor, a control signal for controlling a light-emitting diode, etc., which is not is not limited herein. When the current threshold for OCP is calculated based on the configuration information, a preset multiple, such as 1.2-1.5 times, of a peak to peak current of a service module in the access device may be calculated as the current threshold for OCP, the resistance value of the photoresistor may be calculated based on the current threshold for OCP and the specification of an EFUSE, and then the control signal for controlling the light-emitting diode may be determined based on the control of the photoresistor by the light-emitting diode.

Further, the controller transmits the OCP control information to the logic device. The acquiring OCP control information corresponding to the configuration information of the access device comprises: acquiring the OCP control information corresponding to the configuration information of the access device from the controller. As one feasible implementation, the operation of acquiring the OCP control information corresponding to the configuration information of the access device from the controller comprises: acquiring the OCP control information corresponding to the configuration information of the access device from the controller through an IC bus.

Further, after the OCP control information corresponding to the configuration information of the access device is acquired, the method further comprises: storing the OCP control information in a storage area inside the logic device. In an optional implementation, the logic device receives the OCP control information of the controller and stores same in the storage area. As one feasible implementation, the operation of storing the OCP control information in the storage area of the logic device comprises: storing the OCP control information in a UFM of the logic device.

At S102, outputting a control signal corresponding to the OCP control information to a light-emitting diode to control brightness of the light-emitting diode through the control signal, and control a resistance value of a photoresistor by controlling the brightness of the light-emitting diode, so that an Electronic Fuse (EFUSE) sets a current threshold for OCP based on the resistance value of the photoresistor.

In an optional implementation, the logic device outputs the control signal corresponding to the OCP control information to the light-emitting diode to control the light-emitting diode to be at an appropriate brightness to further control the resistance value of the photoresistor, thereby controlling the current threshold for OCP of the EFUSE. The control signal in the present embodiment may be a PWM signal, that is, the operation of outputting the control signal corresponding to the OCP control information to the light-emitting diode comprises: outputting the PWM control signal corresponding to the OCP control information to the light-emitting diode.

As one feasible implementation, before the control signal corresponding to the OCP control information is output to the light-emitting diode, the method further comprises: receiving the control signal corresponding to the OCP control information transmitted from the controller. In an optional implementation, the controller transmits the OCP control information to the logic device, and simultaneously transmits the control signal corresponding to the OCP control information to the logic device. The control signal is configured to control the brightness of the light-emitting diode when the controller is in a normal operating state.

As one feasible implementation, the operation of outputting the control signal corresponding to the OCP control information to the light-emitting diode, so as to control the brightness of the light-emitting diode through the control signal, and control the resistance value of the photoresistor by controlling the brightness of the light-emitting diode comprises: determining whether the controller is in the normal operating state; in a case where it is determined that the controller is in the normal operating state, switching to a link through which the control signal is received from the controller and is output to the light-emitting diode, so that the controller controls the brightness of the light-emitting diode through the control signal, and controls the resistance value of the photoresistor by controlling the brightness of the light-emitting diode; and in a case where it is determined that the controller is not in the normal operating state, switching to a link through which the control signal is output from the logic device to the light-emitting diode, reading the OCP control information from the storage area, and outputting the control signal corresponding to the OCP control information to the light-emitting diode, so as to control the brightness of the light-emitting diode through the control signal, and control the resistance value of the photoresistor by controlling the brightness of the light-emitting diode.

In an optional implementation, it is determined whether the controller is in the normal operating state by detecting a WDT signal sent from the controller to the logic device. When it is detected that the WDT signal is normal, it is determined that the controller is in the normal operating state, otherwise it is determined that the controller is in an abnormal operating state. In a case where the controller is in the normal operating state, an internal MUX of the logic device is controlled, via an enable signal, to switch to the link through which the control signal is received from the controller and is output from the logic device to the light-emitting diode, so as to achieve transparent transmission of the control signal from the controller, thereby achieving the brightness control of the light-emitting diode by the controller. In a case where the controller is in an abnormal operation state, the internal MUX of the logic device is controlled, via the enable signal, to switch to the link through which the control signal is output from the logic device to the light-emitting diode. The OCP control information is read from the internal storage area, the corresponding control signal is output to control the brightness of the light-emitting diode until the logic device detects that the controller is in the normal operating state again, the control right is returned to the controller again, and the controller continues to control the brightness of the light-emitting diode.

In the embodiment of the present disclosure, the EFUSE is grounded through the photoresistor, the light-emitting diode is arranged near the photoresistor, and the resistance value of the photoresistor may be controlled through the brightness of the light-emitting diode, so that the EFUSE may be controlled to set the corresponding current threshold for OCP by controlling the brightness of the light-emitting diode. When the access device is detected, the current threshold for OCP to be set is determined based on the configuration information of the access device, and the corresponding control signal is transmitted to the light-emitting diode, so as to control the light-emitting diode to be at an appropriate brightness to further control the resistance value of the photoresistor, thereby controlling the current threshold for OCP of the EFUSE. It can be seen that the server OCP method provided by the embodiment of the present disclosure can set the appropriate current threshold for OCP based on different service modules in different access devices, can meet the requirement of the same motherboard being compatible with different service modules, and greatly improve the effectiveness and reliability of OCP and the versatility of the board.

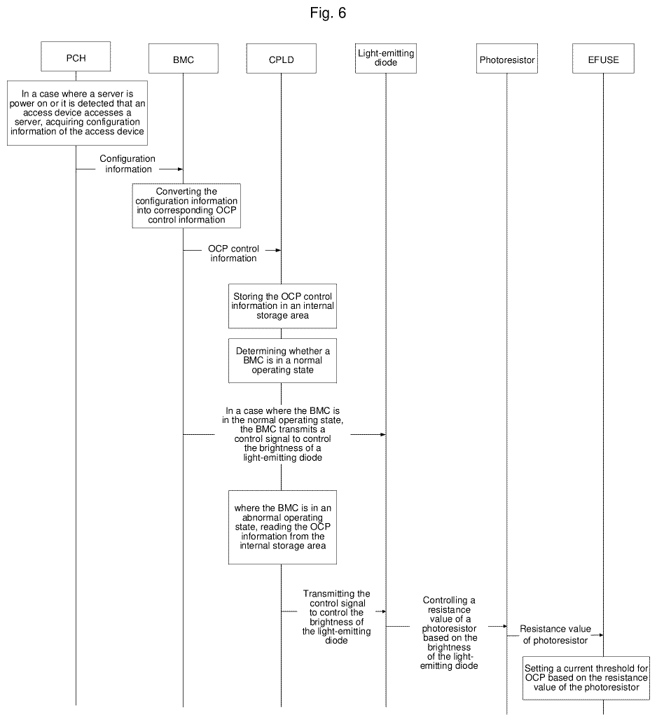

The embodiments of the present disclosure disclose a server OCP method. Compared with the previous embodiment, the technical solution is further explained and optimized in the present embodiment. In some embodiments:
referring to FIG. 6, a flowchart of another server OCP method according to an exemplary embodiment is shown. As shown in FIG. 6, the method comprises the following operations.

At S201, in a case where a server is powered on or an access device is detected to access the server, a PCH acquires configuration information of the access device, and transmits the configuration information to a controller (which may be, but is not limited to, a BMC).

At S202, the controller converts the configuration information into corresponding OCP control information and transmits same to a logic device (which may be, but is not limited to, a CPLD), and simultaneously transmits a control signal corresponding to the OCP control information to the logic device.

At S203, the logic device stores the OCP control information in a storage area inside the logic device.

At S204, the logic device determines whether the controller is in a normal operating state; in a case where it is determined that the controller is in the normal operating state, the logic device switches to a link through which the control signal is received from the controller and is output to a light-emitting diode, and S205 is entered; and in a case where it is determined that the controller is not in the normal operating state, the logic device switches to a link through which the control signal is output from the logic device to the light-emitting diode, and S206 is entered.

At S205, the controller controls the brightness of the light-emitting diode through the control signal, and controls the resistance value of the photoresistor by controlling the brightness of the light-emitting diode.

At S206, the logic device reads the OCP control information from the storage area, and outputs the control signal corresponding to the OCP control information to the light-emitting diode, so as to control the brightness of the light-emitting diode through the control signal.

At S207, controlling the brightness of the light-emitting diode controls the resistance value of the photoresistor.

At S208, an EFUSE sets a current threshold for OCP based on the resistance value of the photoresistor.

In an optional implementation, each time the server is powered on or the access device is hot-swapped, the PCH acquires the configuration information of the access device. The access device here may be a PCIe device, and the configuration information may be a peak-to-peak current of a service module in the access device. The PCH transmits the configuration information to the BMC through an eSPI bus or an LPC bus.

The BMC receives the configuration information transmitted from the PCH, analyzes the configuration information, and determines the OCP control information corresponding to the configuration information. As one feasible implementation, a correspondence between the configuration information and the OCP control information may be pre-stored in a flash, and the BMC may query the OCP control information corresponding to the received configuration information in the flash. As another feasible implementation, the BMC calculates the corresponding OCP control information based on the received configuration information. The OCP control information here may be the current threshold for OCP, the resistance value of the photoresistor, the control signal for controlling the light-emitting diode, etc., which is not is not limited herein. When the current threshold for OCP is calculated based on the configuration information, a preset multiple, such as 1.2-1.5 times, of the peak to peak current of the service module in the access device may be calculated as the current threshold for OCP, the resistance value of the photoresistor may be calculated according to the current threshold for OCP and the specification of the EFUSE, and then the control signal for controlling the light-emitting diode may be determined based on the control of the photoresistor by the light-emitting diode.

Further, the BMC transmits the OCP control information to the CPLD through an I2C, and simultaneously transmits the control signal corresponding to the OCP control information to the CPLD. The control signal is configured to control the brightness of the light-emitting diode when the controller is in the normal operating state. The control signal here may be a PWM waveform, which is not is not limited herein.

The CPLD receives the OCP control information of the BMC and stores same in a storage area inside the logic device. The storage area here may be a UFM storage area, which is not limited herein. The CPLD may detect a state of a WDT signal in real time. In a case where the BMC is in the normal operating state, the CPLD detects that the WDT signal is normal. At this time, an internal MUX is controlled, via an enable signal, to switch to the link through which the control signal is received from the BMC, so as to achieve transparent transmission of the control signal from the BMC, thereby achieving the brightness control of the light-emitting diode by the BMC. In a case where the CPLD detects that the WDT signal is abnormal, it indicates that the BMC is in an initialization or hung state at this time, the CPLD takes over the control right of the light-emitting diode, controls the internal MUX of the CPLD, via the enable signal, to switch to an internal link, reads the OCP control information from the storage area, outputs the corresponding control signal to control the brightness of the light-emitting diode until the CPLD detects that the WDT signal is normal again, and returns the control right to the BMC again, and the BMC continues to control the brightness of the light-emitting diode.

It can be seen that each time the server is powered on or the service module is hot-swapped, the BMC may update the OCP control information and transmit same to the CPLD, and the CPLD stores the OCP control information in the storage area, so as to avoid inconsistency between the OCP control information stored in the storage area of the CPLD and the OCP control information corresponding to the configuration information of the current access device, resulting in abnormal power failure of the service module or failure to provide effective OCP.

When the brightness of the light-emitting diode changes, the resistance value of the photoresistor changes accordingly. The EFUSE sets the corresponding current threshold for OCP based on the change of the resistance value of the photoresistor, so that different current thresholds for OCP are set for different service modules in different access devices.

In the embodiment of the present disclosure, the EFUSE is grounded through the photoresistor, the light-emitting diode is arranged near the photoresistor, and the resistance value of the photoresistor may be controlled through the brightness of the light-emitting diode, so that the EFUSE may be controlled to set the corresponding current threshold for OCP by controlling the brightness of the light-emitting diode. When the access device is detected, the current threshold for OCP to be set is determined based on the configuration information of the access device, and the corresponding control signal is transmitted to the light-emitting diode, so as to control the light-emitting diode to be at an appropriate brightness to further control the resistance value of the photoresistor, thereby controlling the current threshold for OCP of the EFUSE. It can be seen that the server OCP method provided by the embodiment of the present disclosure can set the appropriate current threshold for OCP based on different service modules in different access devices, can meet the requirement of the same motherboard being compatible with different service modules, and greatly improve the effectiveness and reliability of OCP and the universality of the board.

The embodiments of the present disclosure further provide a non-volatile readable storage medium, which may be a non-volatile computer readable storage medium, for example, a memory 3 storing a computer program. The computer program is configured to, when executed by a processor, implement the steps of the server OCP method as described above. The non-volatile computer readable storage medium may be a Ferromagnetic Random Access Memory (FRAM), a Read Only Memory (ROM), a Programmable Read-Only Memory (PROM), an Erasable Programmable Read-Only Memory (EPROM), an Electrically Erasable Programmable Read-Only Memory (EEPROM), a flash memory, a magnetic surface memory, a compact disc, or a Compact Disc Read-Only Memory (CD-ROM).

Those of ordinary skill in the art may understand that all or part of the steps of the above method embodiment may be implemented by a program instructing relevant hardware, the above-mentioned program may be stored in a non-volatile computer readable storage medium, and the program is executed to perform the steps of the above method embodiments.

Or, when being implemented in the form of software functional module and sold or used as an independent product, the above integrated unit of the present disclosure may also be stored in a non-volatile computer readable storage medium. Based on such an understanding, the technical solutions of the embodiments of the present disclosure substantially or parts making contributions to the related art may be embodied in form of software product, and the computer software product is stored in a non-volatile computer readable storage medium, including a plurality of instructions configured to enable an electronic device (which may be a personal computer, a server, a network device, or the like) to perform all or part of the method in each embodiment of the present disclosure.

The above is only the optional implementations of the present disclosure and not intended to limit the scope of protection of the present disclosure. Any variations or replacements apparent to those skilled in the art within the technical scope disclosed by the present disclosure shall fall within the scope of protection of the present disclosure.

1. A server Over Current Protection (OCP) circuit, comprising: a Platform Controller Hub (PCH), a Baseboard Management Controller (BMC), a Complex Programmable Logic Device (CPLD), an Electronic Fuse (EFUSE), a light-emitting diode, and a photoresistor, wherein the PCH is connected to the BMC, the BMC is connected to the CPLD, the CPLD is connected to the EFUSE, the CPLD is grounded through the light-emitting diode, the EFUSE is configured to connect to an access device, and the EFUSE is grounded through the photoresistor;
the PCH is configured to, in a case where a server is powered on or it is detected that the access device connects to the server, acquire the configuration information of the access device, and transmit the configuration information to the BMC;
the BMC is configured to determine OCP control information corresponding to the configuration information, and transmit the OCP control information corresponding to configuration information of the access device to the CPLD;
the CPLD is configured to output a control signal corresponding to the OCP control information to the light-emitting diode to control brightness of the light-emitting diode through the control signal, and to control a resistance value of the photoresistor by controlling the brightness of the light-emitting diode; and
the EFUSE is configured to set a current threshold for OCP based on the resistance value of the photoresistor;
the CPLD is configured to: determine whether the BMC is in a normal operating state; in a case where it is determined that the BMC is in the normal operating state, switch to a link through which the control signal is received from the BMC and is output to the light-emitting diode, so that the BMC controls the brightness of the light-emitting diode through the control signal, and controls the resistance value of the photoresistor by controlling the brightness of the light-emitting diode; and in a case where it is determined that the BMC is not in the normal operating state, switch to a link through which the control signal is output from the CPLD to the light-emitting diode, read the OCP control information from the storage area, and output the control signal corresponding to the OCP control information to the light-emitting diode, so as to control the brightness of the light-emitting diode through the control signal, and control the resistance value of the photoresistor by controlling the brightness of the light-emitting diode.

2. (canceled)

3. The server OCP circuit according to claim 1, wherein the PCH is connected to the BMC through an Enhanced Serial Peripheral Interface (eSPI) bus or a Low Pin Count (LPC) bus.

4. The server OCP circuit according to claim 1, wherein the BMC is configured to convert the configuration information of the access device into the OCP control information and transmit the OCP control information to the CPLD.

5. The server OCP circuit according to claim 1, wherein the BMC is configured to query the OCP control information corresponding to the configuration information of the access device from a flash and transmit the OCP control information to the CPLD.

6. The server OCP circuit according to claim 1, wherein the CPLD is further configured to store the OCP control information in a storage area inside the CPLD.

7. The server OCP circuit according to claim 6, wherein the storage area is a User Flash Memory (UFM).

8. The server OCP circuit according to claim 6, wherein the BMC is further configured to transmit the control signal corresponding to the OCP control information to the CPLD.

9. (canceled)

10. The server OCP circuit according to claim 1, wherein the CPLD is configured to determine whether the BMC is in the normal operating state by detecting a Watchdog Timer (WDT) signal sent from the BMC to the CPLD.

11. The server OCP circuit according to claim 1, wherein the CPLD comprises a Multiplexer (MUX), and the CPLD is configured to control the MUX, via an enable signal, to switch to the link through which the control signal is received from the BMC and is output to the light-emitting diode or the link through which the control signal is output from the CPLD to the light-emitting diode.

12. The server OCP circuit according to claim 1, wherein the control signal is a Pulse Width Modulation (PWM) control signal.

13. A server, comprising the server Over Current Protection (OCP) circuit according to claim 1.

14. A server Over Current Protection (OCP) method, applied to a CPLD of the server OCP circuit according to claim 1, comprising:
acquiring OCP control information corresponding to configuration information of an access device; and
outputting a control signal corresponding to the OCP control information to a light-emitting diode to control brightness of the light-emitting diode through the control signal, and control a resistance value of a photoresistor by controlling the brightness of the light-emitting diode, so that an Electronic Fuse (EFUSE) sets a current threshold for OCP based on the resistance value of the photoresistor.

15. The server OCP method according to claim 14, wherein the acquiring OCP control information corresponding to configuration information of an access device comprises:
acquiring the OCP control information corresponding to the configuration information of the access device from a BMC.

16. The server OCP method according to claim 15, wherein after acquiring the OCP control information corresponding to the configuration information of the access device, the method further comprises:
storing the OCP control information in a storage area inside the CPLD.

17. The server OCP method according to claim 16, wherein before outputting the control signal corresponding to the OCP control information to the light-emitting diode, the method further comprises:
receiving the control signal corresponding to the OCP control information transmit by the BMC.

18. The server OCP method according to claim 17, wherein the outputting a control signal corresponding to the OCP control information to a light-emitting diode to control brightness of the light-emitting diode through the control signal, and control a resistance value of a photoresistor by controlling the brightness of the light-emitting diode comprises:
determining whether the BMC is in a normal operating state;
in a case where it is determined that the BMC is in the normal operating state, switching to a link through which the control signal is received from the BMC and is output to the light-emitting diode, so that the BMC controls the brightness of the light-emitting diode through the control signal, and controls the resistance value of the photoresistor by controlling the brightness of the light-emitting diode; and
in a case where it is determined that the BMC is not in the normal operating state, switching to a link through which the control signal is output from the CPLD to the light-emitting diode, reading the OCP control information from the storage area, and outputting the control signal corresponding to the OCP control information to the light-emitting diode to control the brightness of the light-emitting diode through the control signal, and control the resistance value of the photoresistor by controlling the brightness of the light-emitting diode.

19. The server OCP method according to claim 18,
wherein the switching to a link through which the control signal is received from the BMC and is output to the light-emitting diode comprises: controlling, via an enable signal, a Multiplexer (MUX) inside the CPLD to switch to the link through which the control signal is received from the BMC and is output to the light-emitting diode;
the switching to a link through which the control signal is output from the CPLD to the light-emitting diode comprises: controlling, via the enable signal, the MUX inside the CPLD to switch to the link through which the control signal is output from the CPLD to the light-emitting diode.

20. A non-volatile computer readable storage medium, wherein a computer program is stored in the non-volatile computer readable storage medium, the computer program is configured to, when executed by a processor, implement steps of the server OCP control method according to claim 14.

21. A server, comprising the server Over Current Protection (OCP) circuit according to claim 3.

22. A server, comprising the server Over Current Protection (OCP) circuit according to claim 4.
